(19) United States
(12) Patent Application Publication
(10) Pub. No.: US 2016/0168687 A1
(43) Pub. Date: Jun. 16, 2016

(54) PARTICLE REDUCTION IN A DEPOSITION CHAMBER USING THERMAL EXPANSION COEFFICIENT COMPATIBLE COATING

(71) Applicant: APPLIED MATERIALS, INC., Santa Clara, CA (US)

(72) Inventors: JOTHILINGAM RAMALINGAM, Sunnyvale, CA (US); JIANXIN LEI, Fremont, CA (US)

(21) Appl. No.: 14/620,991

(22) Filed: Feb. 12, 2015

Related U.S. Application Data
(60) Provisional application No. 62/091,610, filed on Dec. 14, 2014.

(51) Int. Cl. C23C 14/22; C23C 4/12; C23C 14/35; C23C 14/50

(52) U.S. Cl. CPC C23C 14/22; C23C 14/50; C23C 4/125; C23C 14/35

(57) ABSTRACT

Methods and apparatus for reducing particles generated in a process carried out in a process chamber are provided herein. In some embodiments, a method of reducing particles generated by a process of depositing a refractory metal on a substrate in a process chamber includes: forming a coating atop an inner surface of the process chamber prior to carrying out the process, wherein the coating has a thermal expansion coefficient that is within 20% of a thermal expansion coefficient of the refractory metal deposited during the process. In some embodiments, a process chamber configured for depositing a refractory metal on a substrate includes: a coating disposed atop an inner surface of the process chamber and having a thermal expansion coefficient that is within 20% of a thermal expansion coefficient of the refractory metal.

### CROSS-REFERENCE TO RELATED APPLICATIONS

This application claims benefit of U.S. provisional patent application Ser. No. 62/091,610, filed Dec. 14, 2014, which is herein incorporated by reference in its entirety.

### FIELD

Embodiments of the present disclosure generally relate to substrate processing equipment, more particularly, to methods and apparatus for reducing the number of particles produced during processes carried out in a process chamber.

### BACKGROUND

In current device fabrication processes, refractory metals such as tungsten (W) and tungsten nitride (WN) are often used to form barrier or liner layers. A refractory metal is typically deposited on a substrate disposed atop a substrate support located within a process chamber. A process such as physical vapor deposition (PVD) may be used to deposit the material. During deposition, however, the refractory metal is not only deposited on the substrate but is also deposited on inner surfaces of the process chamber, such as on a shield, a deposition ring, a cover ring, and/or chamber walls of the process chamber. The deposited refractory metal may form a high-stress film on the substrate and on the inner surfaces of the process chamber.

In addition, when a process is carried out in the process chamber, the inner surface of the process chamber typically goes through a thermal cycle, expanding as the inner surface heats up at the beginning of the cycle and contracting as the inner surface cools down at the end of the cycle. The thermal cycle is repeated in the process chamber each time that a process is carried out. The high stress on the film deposited on the inner surface of the process chamber, in combination with the repeated thermal cycling of the process chamber, undesirably causes the film to delaminate and generate particles. Typically, smaller particles are generated during thermal expansion, and larger particles are generated during thermal contraction, which is known as flaking.

The problem of flaking and particle generation could be addressed by performing preventive maintenance on the process chamber, such as by replacing the shield or other components within the process chamber. However, as device geometries have shrunk, and particle size and particle limit specifications have therefore tightened, the frequency of such preventive maintenance would also increase, undesirably resulting in increased downtime and higher cost of operating the process chamber.

Accordingly, the inventors have provided improved methods and apparatus for reducing the number of particles generated during a process carried out in a process chamber.

### SUMMARY

Methods and apparatus for reducing particles generated in a process carried out in a process chamber are provided herein. In some embodiments, a method of reducing particles generated by a process of depositing a refractory metal on a substrate in a process chamber includes: forming a coating atop an inner surface of the process chamber prior to carrying out the process, wherein the coating has a thermal expansion coefficient that is within 20% of a thermal expansion coefficient of the refractory metal deposited during the process.

In some embodiments, a process chamber configured for depositing a refractory metal on a substrate includes: a coating disposed atop an inner surface of the process chamber and having a thermal expansion coefficient that is within 20% of a thermal expansion coefficient of the refractory metal.

In some embodiments, a process chamber configured for depositing a refractory metal on a substrate includes: an inner surface that includes at least one of a shield, a deposition ring, a cover ring, or chamber walls; an aluminum (Al) coating disposed atop the inner surface and having a thermal expansion coefficient that is greater than five times a thermal expansion coefficient of the refractory metal; and a molybdenum (Mo) coating disposed atop the aluminum coating and having a thermal expansion coefficient that is within 20% of a thermal expansion coefficient of the refractory metal.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a flow diagram illustrating an example of a method of reducing the number of particles generated in a process chamber in accordance with some embodiments of the present disclosure.

FIG. 2 is a schematic cross sectional view of a process chamber in accordance with some embodiments of the present disclosure.

FIG. 3 is a schematic cross sectional view of part of the inner wall of the process chamber shown in FIG. 2 in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure advantageously reduce the number of particles generated in a process chamber during a process. As described in greater detail below, inner surfaces of the process chamber may have a coating that has a thermal expansion coefficient compatible with a thermal expansion coefficient of a material to be deposited on the inner surface of the process chamber. Examples of typical materials to be deposited include refractory metals, such as tungsten (W) or tungsten nitride (WN). As result of the deposited material and the coating having compatible thermal expansion coefficients, the stress on the deposited material during a thermal cycle is decreased so that the number of particles generated by the repeated thermal cycling of the process chamber is reduced.

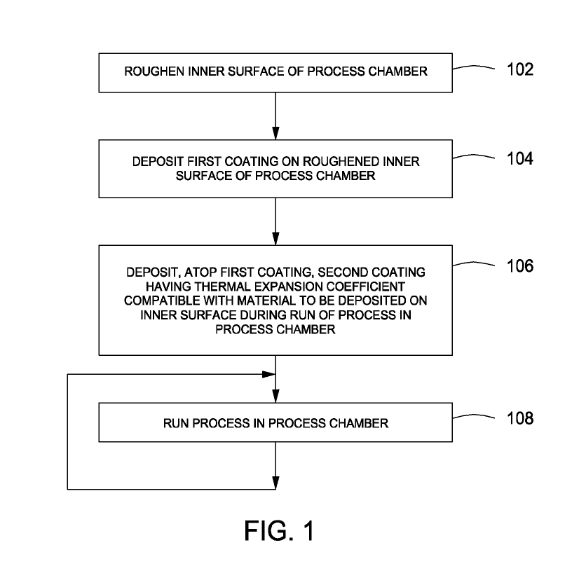

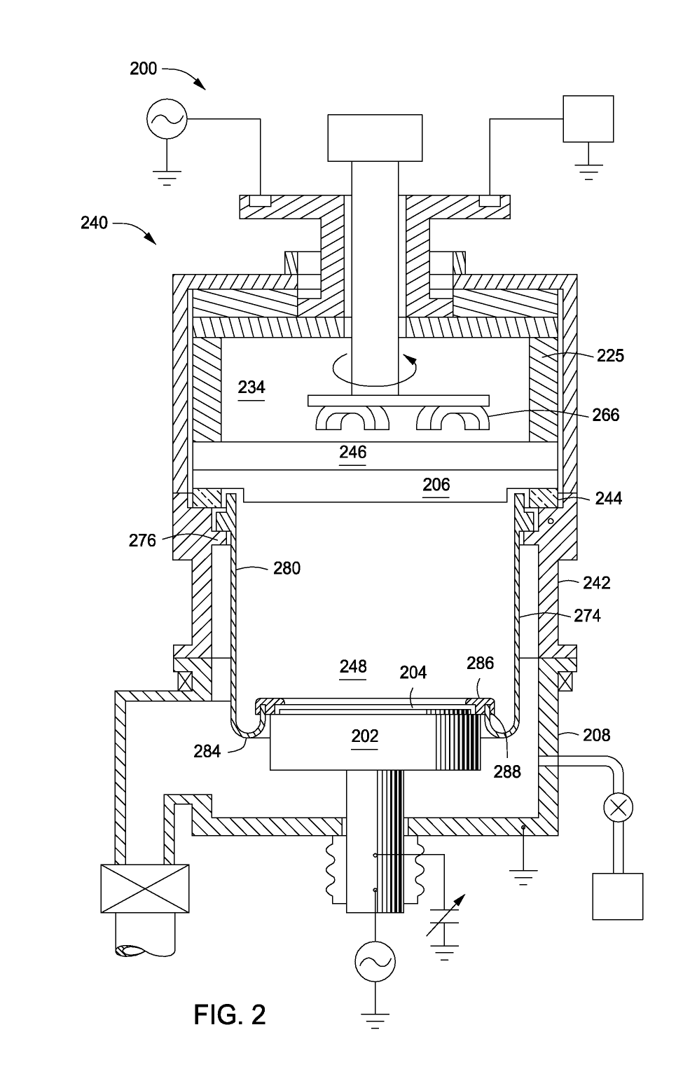

FIG. 1 illustrates an example of a method of reducing the number of particles generated in a process chamber in accordance with embodiments of the present disclosure. In some embodiments, the process chamber shown in FIG. 2 may be used. At 102, in some embodiments, an inner surface of a process chamber is roughened. The inner surface of the process chamber may include, for example, one or more of a shield (also referred to as a process kit shield), a deposition ring, a cover ring, or chamber walls of the process chamber. In some embodiments, the inner surface may comprise aluminum.

When a material is deposited onto a substrate disposed on a substrate holder located in a process chamber during a deposition process, the material may be also deposited on one or more inner surfaces of the process chamber. In some embodiments, the material deposited may be a refractory metal such as tungsten (W) or tungsten nitride (WN). For example, in some embodiments, 2500 Å of tungsten nitride may be deposited on the substrate. In some embodiments, 1000 to 4000 Å of tungsten nitride may be deposited on the substrate. When the inner surface of the process chamber has not been roughened, the deposited material may poorly adhere to an inner surface of a process chamber. For example, a tungsten material does not adhere well to a metal oxide surface, such as may be present an inner surface of a process chamber. The poor adhesion of the deposited material undesirably causes the deposited material to break off from the inner surface of a process chamber into small particles, which are then transported throughout the chamber, and to flake off as larger particles.

By roughening the inner surface of a process chamber, additional surface area is provided which allows for greater mechanical bonding by the deposited material, or by a subsequently deposited first coating, to the inner surface. As a result, greater force is needed to remove the deposited material from the inner surface of the process chamber, which reduces particle generation and limits flaking.

Though the increased surfaced roughness provides an improvement, in some embodiments, a greater reduction in particles generated and flaking may be beneficial. At 104, in some embodiments, a first coating is deposited on the inner surface of a process chamber, which may be a roughened inner surface of the process chamber. For example, one or more of the shield, deposition ring, cover ring, or chamber walls of the process chamber may be coated. The first coating may be an aluminum coating. Spray coating, such as twin-wire-arc spraying (TWAS) or other suitable arc spraying, may be employed to deposit the aluminum or other first coating. The first coating may have a thickness of several thousandths of an inch, such as about 10 to about 12 mils (i.e., about 0.010 to about 0.012 inches).

The first coating increases the roughness of the inner surface of the process chamber, and further increases the roughness of a roughened inner surface, which reduces the generation of particles. The first coating also provides a more uniform roughness than that of the roughened inner surface of a process chamber.

However, a mismatch between the thermal expansion coefficients of the first coating and the deposited material may occur. For example, a mismatch exists between the thermal expansion coefficient of an aluminum first coating and the thermal expansion coefficient of a deposited refractory metal. As an example, the thermal expansion coefficient of tungsten (W) is 2.5, whereas the thermal expansion coefficient of aluminum is 13.1, which is more than five times greater than the thermal expansion coefficient of tungsten. The mismatch in thermal expansion coefficients, in combination with the repeated thermal cycling of the process chamber, increases the stress in the deposited material which may cause the deposited material to delaminate from the inner surface of the process chamber, resulting in particle generation and flaking. As a result, the numbers of particles generated by each run of a process increases as the number of runs increases, namely, as the number of thermal cycles increases.

Therefore, in some embodiments and as shown at 106, a second coating may be provided on the inner surface of the process chamber, wherein the second coating has a thermal expansion coefficient that is compatible with the thermal expansion coefficient of the material deposited on the inner surface of the process chamber. The second coating may be deposited directly atop the first coating, directly atop the roughened inner surface of a process chamber, or directly atop a non-roughened inner surface of a process chamber. The second coating may be deposited using arc spray coating or by sputtering from a target. The second coating may have a thickness of about 25 to about 35 μm. In some embodiments, the coating may have a thermal expansion coefficient that is within about 20% of the thermal expansion coefficient of the deposited material, which may be a refractory metal. For example, a molybdenum (Mo) coating having a thermal expansion coefficient of about 3.0 may be provided to reduce the number of particles produced from a deposited tungsten (W) material, whose thermal expansion coefficient is 2.5.

Next, at 108, processes are successively carried out in the process chamber. The processes may include deposition processes, such as physical vapor deposition (PVD), which may deposit tungsten (W), tungsten nitride (WN), or other refractory metal on a substrate. The second coating, which has a thermal expansion coefficient that is compatible with the thermal expansion coefficient of the deposited material, reduces the stress in the deposited material generated during each thermal cycle of the process chamber. As a result, the number of particles generated by each run of a process advantageously remains relatively constant as the number of runs of the process increases, whereas when only a first coating is provided, the numbers of particles produced by each run of the process increases as the number of runs of the process increases. Further advantageously, because the number of particles generated by each run of a process remains relatively constant as the number of runs of the process increases, preventive maintenance may also be carried out less frequently, and as a result, downtime and operating costs may also decrease.

FIG. 2 depicts a schematic, cross-sectional view of an illustrative physical vapor deposition chamber (process chamber 200) having first and second coatings in accordance with some embodiments of the present disclosure. Examples of PVD chambers suitable for modification and use in accordance with the present disclosure include the ALPS® Plus, SIP ENCORE®, and other PVD processing chambers commercially available from Applied Materials, Inc., of Santa Clara, Calif. Other processing chambers from Applied Materials, Inc. or other manufactures may also benefit from the inventive apparatus disclosed herein.

The process chamber 200 contains a substrate support 202 for receiving a substrate 204, a sputtering source, such as a target 206, and a process kit shield 274 disposed between the substrate support 202 and the target 206. The substrate support 202 may be located within a grounded enclosure wall 208, which may be a chamber wall (as shown) or a grounded shield. (A grounded shield 240 is shown covering at least some portions of the process chamber 200 above the target 206. In some embodiments, the grounded shield 240 may extend below the target to enclose also the substrate support 202).

The target 206 may be supported on a grounded, conductive sidewall of the chamber, referred to in some embodiments as an adapter 242, through a dielectric isolator 244. In some embodiments, the grounded, conductive sidewall of the chamber, or adapter 242, may be fabricated from aluminum. The target 206 comprises a material, such as tungsten (W) or other refractory metal, which is to be deposited on the substrate 204 during sputtering, possibly in combination with another species, such as to form tungsten nitride (WN) or other material.

In some embodiments, a backing plate 246 may be coupled a back surface 232 of the target 206 (i.e., the surface opposite the target surface facing the substrate support 202. The backing plate 246 may comprise a conductive material, such as copper-zinc, copper-chrome or the same material as the target, such that RF and/or DC energy can be coupled to the target 206 via the backing plate 246. Alternatively, the backing plate 246 may be a non-conductive material which may include conductive elements, such as electrical feedthroughs or the like, for coupling the target 206 to a conductive member 225 to facilitate providing at least one of RF or DC power to the target 206. The backing plate 246 may also or alternatively be included, for example, to improve structural stability of the target 206.

A rotatable magnetron assembly 236 may be positioned proximate to the back surface 232 of the target 206. The rotatable magnetron assembly 236 includes a plurality of magnets 266 supported by a base plate 268. The magnets 266 produce an electromagnetic field around the top of the process chamber 200 and are turned to rotate the electromagnetic field which varies the plasma density of the process in a manner that more uniformly sputters the target 206.

The substrate support 202 includes a material-receiving surface that faces the principal surface of the target 206 and which supports the substrate 204 to be sputter coated in planar position opposite to the principal surface of the target 206. The substrate support 202 may support the substrate 204 in a central region 248 of the process chamber 200. The central region 248 may be defined as the region located above the substrate support 202 during processing (for example, between the target 206 and the substrate support 202 when in a processing position).

A process kit shield 274 may be coupled to the process chamber 200 in any suitable manner that retains the process kit shield 274 in a given position within the process chamber 200. For example, in some embodiments, the process kit shield 274 may be connected to a ledge 276 of the adapter 242. The adapter 242, in turn, is sealed and grounded to the enclosure wall 208. Generally, the process kit shield 274 extends downwardly along the walls of the adapter 242 and the enclosure wall 208 to below a top surface of the substrate support 202 and then upwardly until reaching a top surface of the substrate support 202 (e.g., forming a U-shaped portion 284 at the bottom). Alternatively, instead of a U-shaped portion 284, the bottommost portion of the process kit shield may have another suitable configuration. A cover ring 286 may rest atop an upwardly extending lip 288 of the process kit shield 274 when the substrate support 202 is in a lower, loading position. The cover ring 286 may rest on the outer periphery of the substrate support 202 when the substrate support 202 is in an upper, deposition position to protect the substrate support 202 from sputter deposition. One or more additional deposition rings (one deposition ring 203 shown in FIG. 2) may be used to shield the periphery of the substrate support 202 from deposition. One or both of the process kit shield 274 and the cover ring 286 may be fabricated from aluminum.

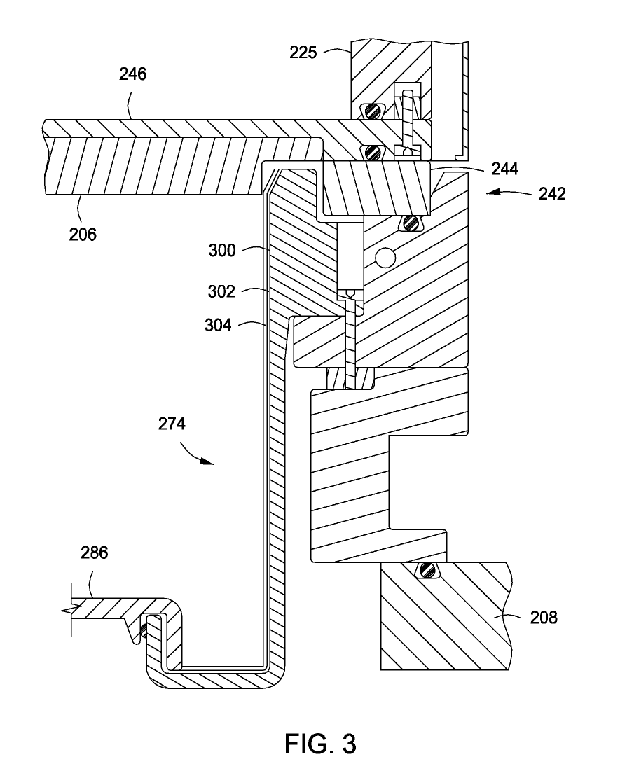

FIG. 3 shows an enlarged schematic, cross-sectional view of part of the process chamber 200 of FIG. 2. In some embodiments, a process volume facing surface 300 of the process kit shield 274 may be roughened as described above in connection with 102 of FIG. 1. In some embodiments, the process volume facing surface 300 of the process kit shield 274 may be coated with a first coating 302 as described above regarding 104 of FIG. 1. Additionally, in accordance with some embodiments of the present disclosure, a second coating 304 is formed on the process volume facing surface 300 of the process kit shield 274 as described above with respect to 106 of FIG. 1.

While the foregoing is directed to embodiments of the present disclosure, other and further embodiments of the disclosure may be devised without departing from the basic scope thereof.

1. A method of reducing particles generated by a process of depositing a refractory metal on a substrate in a process chamber, comprising:
forming a coating atop an inner surface of the process chamber prior to carrying out the process, wherein the coating has a thermal expansion coefficient that is within 20% of a thermal expansion coefficient of the refractory metal deposited during the process.

2. The method of claim 1, wherein the refractory metal is deposited on the coating during the process.

3. The method of claim 2, wherein the refractory metal deposited on the coating includes tungsten (W).

4. The method of claim 2, wherein the refractory metal is further deposited on a substrate located on a substrate support disposed within the process chamber during the process.

5. The method of claim 1, wherein the coating is formed by sputtering or arc-spraying.

6. The method of claim 1, wherein the coating includes molybdenum (Mo).

7. The method of claim 1, wherein the coating has a thickness of about 25 to about 35 μm.

8. The method of claim 1, further comprising:
forming a further coating on the inner surface of the process chamber prior to forming the coating, the further coating having a thermal expansion coefficient that is greater than five times the thermal expansion coefficient of the refractory metal deposited during the process.

9. The method of claim 8, wherein the further coating includes aluminum (Al).

10. The method of claim 8, wherein the further coating is formed on the inner surface of the process chamber by arc-spraying.

11. The method of claim 1, wherein the inner surface of the process chamber includes at least one of a shield, a deposition ring, a cover ring, or chamber walls.

12. A process chamber configured for depositing a refractory metal on a substrate, comprising:
a coating disposed atop an inner surface of the process chamber and having a thermal expansion coefficient that is within 20% of a thermal expansion coefficient of the refractory metal.

13. The process chamber of claim 12, wherein the coating includes molybdenum (Mo).

14. The process chamber of claim 12, wherein the coating has a thickness of about 25 to about 35 μm.

15. The process chamber of claim 12, further comprising:
a further coating disposed between the inner surface of the process chamber and the coating, the further coating having a thermal expansion coefficient that is greater than five times the thermal expansion coefficient of the refractory metal.

16. The process chamber of claim 15, wherein the further coating includes aluminum (Al).

17. The process chamber of claim 15, wherein the further coating has a thickness of about 0.010 to about 0.012 inches.

18. The process chamber of claim 12, wherein the refractory metal includes tungsten (W).

19. The process chamber of claim 12, wherein the inner surface of the process chamber includes at least one of a shield, a deposition ring, a cover ring, or chamber walls.

20. A process chamber configured for depositing a refractory metal on a substrate, comprising:
an inner surface that includes at least one of a shield, a deposition ring, a cover ring, or chamber walls;
an aluminum (Al) coating disposed atop the inner surface and having a thermal expansion coefficient that is greater than five times a thermal expansion coefficient of the refractory metal; and
a molybdenum (Mo) coating disposed atop the aluminum coating and having a thermal expansion coefficient that is within 20% of a thermal expansion coefficient of the refractory metal.
